(19) United States
(12) Patent Application Publication
(10) Pub. No.: US 2014/0291701 A1
(43) Pub. Date: Oct. 2, 2014

(54) SEMICONDUCTOR DEVICE

(71) Applicant: Yukimasa Hayashida, Fukuoka (JP)

(72) Inventor: Yukimasa Hayashida, Fukuoka (JP)

(73) Assignee: MITSUBISHI ELECTRIC CORPORATION, Chiyoda-ku, Tokyo (JP)

(21) Appl. No.: 14/353,990

(22) PCT Filed: Mar. 5, 2012
(86) PCT No.: PCT/JP2012/055507

§ 371 Date: Apr. 24, 2014

(51) Int. Cl. H01L 49/02; H01L 29/16; H01L 23/498

(52) U.S. Cl. CPC H01L 28/22; H01L 23/49838; H01L 29/1608
USPC 257/77

(57) ABSTRACT

An object of the present invention is to provide a semiconductor device that allows the life of solder joint parts of electronic components to be increased. The semiconductor device according to the present invention includes ceramic, an upper pattern formed on the ceramic, and a resistor connected onto the upper pattern via solder. The upper pattern has a portion formed in a recess shape, the portion being connected to the resistor via the solder.

### TECHNICAL FIELD

The present invention relates to semiconductor devices provided inside with semiconductor elements and electronic components disposed near the semiconductor elements.

### BACKGROUND ART

In a semiconductor device, electronic components such as resistors for adjusting the balance between input signals input to the semiconductor elements, individually, are provided near semiconductor elements via solder. The electronic components are joined (connected) to a top of an electrode pattern formed on a substrate (for example, see Patent Document 1).

### PRIOR ART DOCUMENT

### Patent Document

Patent Document 1: Japanese Patent Application Laid-Open No. 2007-237212

### SUMMARY OF INVENTION

### Problems to Be Solved by the Invention

With advances in the high-temperature operation of semiconductor elements in recent years, it has been required that material used around (near) the semiconductor elements also be improved in reliability under high temperatures. It has also been required that solder joint parts of electronic components be improved in reliability under high temperatures as compared with conventional ones. In order to improve the reliability of solder joint parts of electronic components, solder joint parts need to be formed in such a manner as to withstand high-temperature operation of semiconductor elements to increase their life. However, no measures have previously been taken to increase the life of solder joint parts of electronic components.

The present invention has been made to solve these problems, and has an object of providing semiconductor devices that allow the life of solder joint parts of electronic components to be increased.

### Means for Solving the Problems

In order to solve the above problems, a semiconductor device according to the present invention includes a substrate, an electrode pattern formed on the substrate, and an electronic component connected onto the electrode pattern via solder. The electrode pattern has a portion formed in a recess shape, the portion being connected to the electronic component via the solder.

### Effects of the Invention

According to the present invention, a substrate, an electrode pattern formed on the substrate, and an electronic component connected onto the electrode pattern via solder are provided. The electrode pattern has a portion formed in a recess shape, the portion being connected to the electronic component via the solder. Thus the life of solder joint parts of the electronic component can be increased.

### BRIEF DESCRIPTION OF DRAWINGS

FIG. 1 is a diagram illustrating the configuration of a semiconductor device according to a first embodiment.

FIG. 2 is a diagram illustrating the configuration of a semiconductor device according to an underlying technology.

### DESCRIPTION OF EMBODIMENT

An embodiment of the present invention will be described below with reference to the drawings.

<Underlying Technology>

First, a technology that underlies the present invention (underlying technology) will be described.

FIG. 2 is a diagram illustrating the configuration of a semiconductor device according to the underlying technology.

In FIG. 2, the configuration of a resistor 4 (electronic component) provided in the semiconductor device is shown. The resistor 4 is disposed near a semiconductor element (not shown) also provided in the semiconductor device.

As shown in FIG. 2, an upper pattern 2 is formed on ceramic 1, and a lower pattern 3 is formed opposite to the upper pattern 2 on the ceramic 1. The upper pattern 2 and the lower pattern 3 show electrode patterns made of conductors formed on the ceramic 1.

The resistor 4 is disposed in such a manner as to straddle a space in the upper pattern 2. Electrode portions of the resistor 4 are joined (connected) to the upper pattern 2 via solder 5.

The surface of the upper pattern 2 has a flat shape with no steps.

As described above, with advances in the high-temperature operation of semiconductor elements in recent years, it has been required that solder joint parts of the resistor 4 (electronic component) also be improved in reliability (increased in life) under high temperatures. However, no measures have been taken to increase the life of the solder joint parts of the resistor 4 provided in the semiconductor device according to the underlying technology as shown in FIG. 2, which can cause a problem that the solder 5 separates from the solder joint parts when the semiconductor element operates at high temperatures, or the like.

The present invention has been made to solve the above problems, and will be described in detail below.

### Embodiment

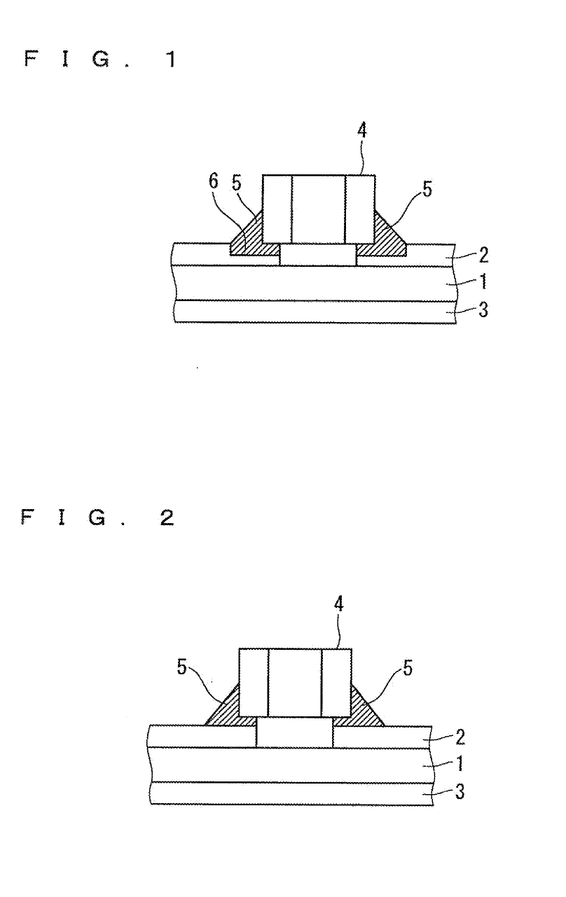

FIG. 1 is a diagram illustrating the configuration of a semiconductor device according to an embodiment of the present invention.

In FIG. 1, the configuration of a resistor 4 (electronic component) provided in the semiconductor device is shown. The resistor 4 is disposed near a semiconductor element (not shown) that is also provided in the semiconductor device. The semiconductor element may be SiC, for example. Since SiC operates at high temperatures, using SiC as a semiconductor element is particularly effective in the present invention.

As shown in FIG. 1, an upper pattern 2 is formed on ceramic 1 constituting a substrate, and a lower pattern 3 is formed opposite to the upper pattern 2 on the ceramic 1. The upper pattern 2 and the lower pattern 3 show electrode patterns made of conductors formed on the ceramic 1. The semiconductor element is disposed on the ceramic 1 or on the upper pattern 2 near the resistor 4.

The resistor 4 is disposed in such a manner as to straddle a space in the upper pattern 2. Electrode portions of the resistor 4 are joined (connected) to the upper pattern 2 via solder 5.

In a surface of the upper pattern 2, stepped portion 6 in a recess shape are formed. The resistor 4 is disposed above the stepped portion 6, and is joined to the upper pattern 2 via the solder 5. At this time, the solder 5 is formed to cover the bottom surface and the side surface of the stepped portion 6.

That is, the semiconductor device according to the embodiment includes the ceramic 1 (substrate), the upper pattern 2 (electrode pattern) formed on the ceramic 1, and the resistor 4 (electronic component) joined (connected) onto the upper pattern 2 via the solder 5, in which the upper pattern 2 has a portion formed in a recess shape (stepped portion 6) that is connected to the resistor 4 via the solder 5.

The above-described configuration increases the amount of the solder 5 and also increases the area of the solder 5 joined to the resistor 4 and the upper pattern 2, as compared with conventional ones. Thus, the joint strength of the solder 5 can be made greater than before.

From the above, according to the embodiment, the joint strength of the solder 5 can be increased by forming the stepped portion 6 on the upper pattern 2. Consequently, even when the resistor 4 (electronic component) is disposed near the semiconductor element, the life of the solder joint parts of the resistor 4 can be increased. Further, it is particularly effective to apply to the present invention a semiconductor element that operates at high temperatures such as SiC, thereby improving the reliability of an entire semiconductor device provided with the semiconductor element.

The embodiment has been described using the resistor 4 as an example of an electronic component, but electronic components other than the resistor 4 may be used.

In the present invention, the embodiment can be modified and omitted as appropriate within the scope of the invention.

### REFERENCE SIGN LIST

1 ceramic, 2 upper pattern, 3 lower pattern, 4 resistor, 5 solder, 6 stepped portion.

1. A semiconductor device comprising:
a substrate;
an electrode pattern formed on said substrate; and
an electronic component connected onto said electrode pattern via solder;
said electrode pattern having a portion formed in a recess shape, the portion being connected to said electronic component via said solder.

2. The semiconductor device according to claim 1, wherein said electronic component is a resistor.

3. The semiconductor device according to claim 1, wherein said electronic component is disposed near a semiconductor element disposed on said substrate or on said electrode pattern.

4. The semiconductor device according to claim 3, wherein said semiconductor element is formed of SiC.
